(19) United States
(12) Patent Application Publication
(10) Pub. No.: US 2010/0245740 A1
(43) Pub. Date: Sep. 30, 2010

(54) Transflective Liquid Display Panel and Manufacturing Method for Lower Substrate Thereof

(75) Inventors: Hsiu-Lin Chan, Cyonglin Township (TW); Cheng-Yen Yeh, Tanzih Township (TW); Chien-Chang Lee, Madou Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: WINTEK CORPORATION, Taichung (TW)

(21) Appl. No.: 12/730,404

(22) Filed: Mar. 24, 2010

(30) Foreign Application Priority Data
Mar. 26, 2009 (TW) 98109893

(51) Int. Cl. G02F 1/1335; H01L 33/00

(52) U.S. Cl. 349/114; 438/23; 257/E33.055

(57) ABSTRACT

A transflective LCD panel and a manufacturing method for lower substrate thereof are provided. The transflective LCD panel includes an upper substrate, a liquid crystal layer and a lower substrate. The liquid crystal layer, including a plurality of liquid crystal molecules, is disposed between the upper substrate and the lower substrate. The lower substrate includes an active array structure layer, a plurality of transparent pixel electrodes and a cushion layer. The active array structure layer includes a plurality of transparent bottom electrodes, transistor structures and an insulation layer. The insulation layer covers the transparent bottom electrode. The transparent pixel electrodes are formed on the active array structure layer, wherein each transparent pixel electrode partially overlaps the corresponding transparent bottom electrode and the overlap is located at the transmissive region. The cushion layer formed on the active array structure layer has a reflective metal layer for reflecting the environment light.

This application claims the benefit of Taiwan application Serial No. 98109893, filed Mar. 26, 2009, the subject matter of which is incorporated herein by reference.

### BACKGROUND OF THE INVENTION

1. Field of the Invention

The invention relates in general to a transflective LCD panel and a manufacturing method for a lower substrate thereof, and more particularly to a transflective LCD panel with transparent bottom electrode and a manufacturing method for a lower substrate thereof.

2. Description of the Related Art

According to the reflection type, liquid crystal display (LCD) panels are divided into transmissive type, reflective type and tranflective type. The transmissive LCD panel, which achieves transmissive display through a backlight source, maintains excellent display effect no matter the light is normal or dark. However, the displayed contents are hard to recognize when the transmissive LCD panel is exposed to the outdoor light. The reflective LCD panel uses the environment light and can do without extra light source, and has excellent display effect when the environment light is sufficient. However, when the environment light is insufficient, the displayed contents are hard to recognize. The tranflective LCD panel combines the advantages of the transmissive LCD panel and the reflective LCD panel.

Let the tranflective LCD panel be taken for example. The storage capacitor structure is normally formed by overlapping the first metal layer on the second metal layer, and such storage capacitor structure is called the metal insulator metal (MIM) storage capacitor. However, the MIM storage capacitor is opaque. To avoid decreasing the aperture ratio of the transmissive region of the pixel structure, the MIM storage capacitor is formed at the reflection region of the pixel structure.

However, the resolution requirement of the display panel is getting higher and higher. To meet such trend of increasing resolution requirement, the area of the pixel structure is getting smaller and smaller. Consequently, the area of the reflection region of the pixel structure also becomes smaller accordingly, and the display quality is affected due to insufficient storage capacitor. Besides, if the area of the storage capacitor structure is increased so as to generate the designed capacitor of the storage capacitor, the opaque metal of the storage capacitor structure needs to be extended to the transmissive region of the pixel structure, hence reducing the aperture ratio of the transmissive region of the pixel structure.

### SUMMARY OF THE INVENTION

The invention is directed to a transflective LCD panel and a manufacturing method for a lower substrate thereof. The storage capacitor structures disposed at the transmissive region of the pixel structure of the transflective LCD panel uses a transparent structure formed by a transparent bottom electrode and a transparent pixel electrode, so that the storage capacitor is increased without decreasing the aperture ratio of the transmissive region of the pixel structure, and the design requirements for high-resolution display panel are satisfied.

According to a first aspect of the present invention, a transflective LCD panel is provided. The transflective LCD panel includes an upper substrate, a liquid crystal layer and a lower substrate. The liquid crystal layer includes a plurality of liquid crystal molecules. The lower substrate is substantially parallel to the upper substrate, wherein the liquid crystal layer is disposed between the upper substrate and the lower substrate. The lower substrate includes a bottom substrate, an active array structure layer, a plurality of transparent pixel electrodes, a cushion layer and a reflective metal layer. The active array structure layer includes a plurality of transparent bottom electrodes, a plurality of transistor structures, at least an insulation layer, a plurality of scan lines and a plurality of data lines, which are all formed on the bottom substrate. The data lines and the scan lines define a plurality of pixels. The insulation layer covers the transparent bottom electrode. A plurality of transparent pixel electrodes are formed on the active array structure layer, wherein each transparent pixel electrode partially overlaps the corresponding transparent bottom electrode to form a plurality of storage capacitor structures. The cushion layer is formed on the active array structure layer and has a plurality of recesses for respectively exposing the transparent pixel electrode and enabling the liquid crystal molecules to be arranged in a multi-domain. The reflective metal layer is formed on the cushion layer for reflecting the light. Wherein at least a portion of one of the transparent bottom electrodes and at least a portion of the corresponding transparent pixel electrode are disposed at the transmissive region of the corresponding pixel.

According to a second aspect of the present invention, a manufacturing method for lower substrate of transflective LCD panel is provided. The transflective LCD panel further includes an upper substrate and a liquid crystal layer. The liquid crystal layer includes a plurality of liquid crystal molecules. The lower substrate is substantially parallel to the upper substrate, wherein the liquid crystal layer is disposed between the upper substrate and the lower substrate. The manufacturing method includes the following steps. A lower substrate is provided, wherein the lower substrate includes a bottom substrate. An active array structure layer is formed on the bottom substrate, wherein the active array structure layer includes a plurality of transparent bottom electrodes, a plurality of transistor structures, at least an insulation layer, a plurality of scan lines and a plurality of data lines, which are all formed on the bottom substrate. The first insulation layer covers the transparent bottom electrode. The data lines and the scan lines define a plurality of pixels. The insulation layer covers the transparent bottom electrode. A plurality of transparent pixel electrodes is formed on the active array structure layer, wherein each transparent pixel electrode partially overlaps the corresponding transparent bottom electrode to form a plurality of storage capacitor structures. A cushion layer is formed on the active array structure layer, wherein the cushion layer has a plurality of recesses for respectively exposing the transparent pixel electrodes and enabling the liquid crystal molecules to be arranged in a multi-domain. A reflective metal layer is formed on the cushion layer for reflecting the light. Wherein at least a portion of one of the transparent bottom electrodes and at least a portion of the corresponding transparent pixel electrode are disposed at the transmissive region of the corresponding pixel.

The invention will become apparent from the following detailed description of the preferred but non-limiting embodiments. The following description is made with reference to the accompanying drawings.

### BRIEF DESCRIPTION OF THE DRAWINGS

FIG. 1 shows a transflective LCD panel according to a preferred embodiment of the invention;

FIG. 2 shows a lower substrate of FIG. 1 viewed along a direction V1;

FIG. 3 shows a cross-sectional view of the lower substrate of FIG. 2 viewed along a direction 3-3′;

FIG. 4 shows a flowchart of a manufacturing method for a lower substrate of a transflective LCD panel according to a preferred embodiment of the invention;

FIG. 5A shows a bottom substrate of FIG. 3;

FIG. 5B shows a bottom substrate of FIG. 5A with an active array structure layer;

FIG. 5C shows a bottom substrate of FIG. 5B with a transparent pixel electrode; and

FIG. 5D shows a bottom substrate of FIG. 5C with a cushion layer.

### DETAILED DESCRIPTION OF THE INVENTION

The invention embodiment provides a transflective LCD panel and a manufacturing method for a lower substrate thereof. The storage capacitor structure disposed at the transmissive region of the pixel structure is a transparent structure formed by a transparent bottom electrode and a transparent pixel electrode, so that the storage capacitor can be increased without decreasing the aperture ratio of the transmissive region of the pixel structure.

A preferred embodiment is exemplified below for elaborating the invention. However, the embodiment is merely an example of the implementations under the spirit of the invention, and the disclosure and drawings of the embodiment below are not for limiting the scope of protection of the invention.

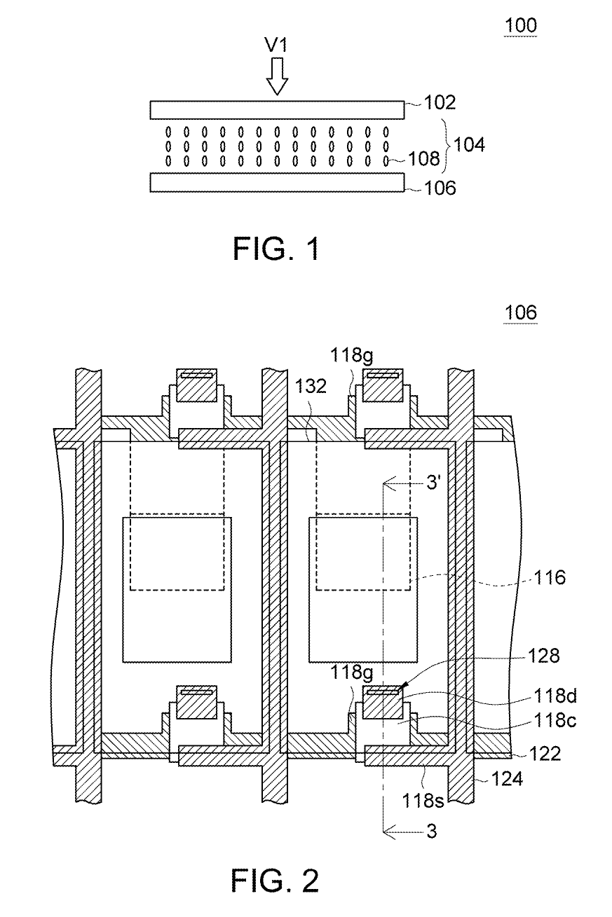

Referring to FIG. 1, a transflective LCD panel according to a preferred embodiment of the invention is shown. The transflective LCD panel 100 includes an upper substrate 102, a liquid crystal layer 104 and a lower substrate 106. The liquid crystal layer 104 includes a plurality of liquid crystal molecules 108. The lower substrate 106 is substantially parallel to the upper substrate 102, and the liquid crystal layer 104 is disposed between the upper substrate 102 and the lower substrate 106.

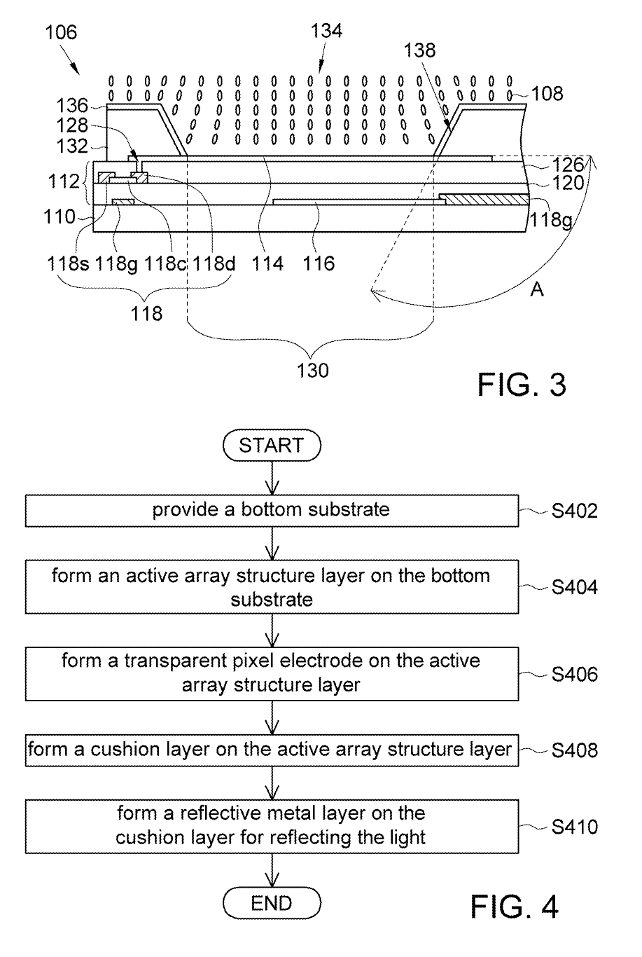

Referring to both FIG. 2 and FIG. 3. FIG. 2 shows a lower substrate of FIG. 1 viewed along a direction V1. FIG. 3 shows a cross-sectional view of the lower substrate of FIG. 2 viewed along a direction 3-3′. The lower substrate 106 includes a bottom substrate 110, an active array structure layer 112, a plurality of transparent pixel electrodes 114, a cushion layer 132 and a reflective metal layer 136. The cushion layer 132 is made from an organic material for example.

The active array structure layer 112 includes a plurality of transparent bottom electrode 116, a plurality of transistor structures 118, an insulation layer 120, a plurality of scan lines 122, a plurality of data lines 124 and a passivation layer 126. The transistor structure 118 includes a gate 118g, a source 118s, a drain 118d and a channel layer 118c. The gate 118g and the scan lines 122 are located on the same metal layer, and the source 118s and the data lines 124 are also located on the same metal layer. The insulation layer 120 covers the transparent bottom electrode 116.

Besides, the data lines 124 and the scan lines 122 define a plurality of pixels, wherein each pixel includes a transistor structure 118, a transparent bottom electrode 116, an insulation layer 120, a passivation layer 126 and a transparent pixel electrode 114. The scan lines 122 are respectively electrically connected to a gate 118g of the transistor structure 118. The data lines 124 are electrically connected to a source 118s of the transistor structure 118. The scan lines 122 are electrically isolated from the data lines 124 through the insulation layer 120, and the transparent pixel electrode 114 is electrically connected to a drain 118d of the transistor structure 118 through a contact hole 128. At least a portion of the corresponding transparent bottom electrode 116 and at least a portion of the transparent pixel electrode 114 are disposed at the transmissive region 130 of the corresponding pixel.

In the present embodiment of the invention, a part of the transparent bottom electrode 116 is located at the transmissive region 130 and the other part is extended to be under the reflective metal layer 136 from the right-hand side of FIG. 3 so as to be electrically connected to the gate 118g. Thus, the aperture ratio is not decreased by any opaque structure at the transmissive region 130 such as the gate 118g for example.

Compared with the LCD with MIM storage capacitor, the storage capacitor structure of the transflective LCD panel 100 of the present embodiment of the invention is a transparent structure formed by a transparent bottom electrode 116 and a transparent pixel electrode 114, and does not have to be located at the reflective electrode region lest the aperture ratio of the transmissive region might be decreased. Thus, the storage capacitor is increased without decreasing the aperture ratio of the transmissive region of the pixel structure.

Let the 2.8″ (VGA) transflective LCD panel with 289 PPI resolution level be taken for example. Under the circumstances that the design of the transparent bottom electrode of the present embodiment of the invention is not adopted, when the storage capacitor equals 0.063 pF, the aperture ratio of the transmissive region is 23.17%, and when the storage capacitor is increased from 0.063 pF to 0.1048 pF, the aperture ratio of the transmissive region will change to 13.58% from 23.17%. The present embodiment of the invention, which adopts the design of the transparent bottom electrode, has high storage capacitor and high aperture ratio at the same time. For example, when the storage capacitor is as high as 0.1216 pF, the aperture ratio of the transmissive region can also be as high as 31.97%. Thus, the design of the transparent bottom electrode of the present embodiment of the invention does not decrease the aperture ratio of the transmissive region at all, but also increases the storage capacitor.

Thus, the transflective LCD panel of the present embodiment of the invention is more flexible in the design. During the stage of product design, when the circuit designer finds out that the storage capacitor is insufficient, the circuit designer only needs to dispose a transparent storage capacitor structure at the transmissive region of the pixel structure. By doing this, the insufficient capacitor is compensated without decreasing the aperture ratio of the transmissive region of the pixel structure.

Besides, the transflective LCD panel 100 of the present embodiment of the invention enables the liquid crystal molecules 108 to be arranged in a multi-domain. As indicated in FIG. 3, the cushion layer 132 is formed on the active array structure layer 112, and has a plurality of recesses 134 for respectively exposing the transparent pixel electrode 114. Besides, an obtuse angle A is contained between the side-wall 138 of the recesses 134 and the corresponding transparent pixel electrode 114 so that the liquid crystal molecules 108 are arranged in a multi-domain to increase the range of angle of view in the transflective LCD panel 100 and reduce the response time of the liquid crystal molecules 108. Besides, the reflective metal layer 136 is formed on the cushion layer 132 for reflecting the environment light.

The area covered by the reflective metal layer 136 becomes a reflection region of the pixel structure. As indicated in FIG. 2, the reflective metal layer 136 can only cover a part of the data lines 124, a part of the scan lines 122 and at least a part of the transistor structure 118 as to properly increase the area of the reflection region. However, the reflective metal layer 136 can also cover the entire transistor structure 118.

As the storage capacitor structures of the present embodiment of the invention is exemplified by a type of Cs-on-Gate, the transparent bottom electrode 116 is electrically connected to the gate 118g. However, the storage capacitor structure of the invention does not have to be a type of Cs-on-Gate. According to the LCD panel technology, the storage capacitor structure can also be a type of Cs-on-Common. For example, when the storage capacitor structure of an embodiment of the invention is a type of Cs-on-Common, the transparent bottom electrode 116 of each pixel can be electrically connected to a common electrode (not illustrated).

A manufacturing method for a transflective LCD panel according to a preferred embodiment of the invention is disclosed below. Referring to FIG. 4, a flowchart of a manufacturing method for a lower substrate of a transflective LCD panel according to a preferred embodiment of the invention is shown.

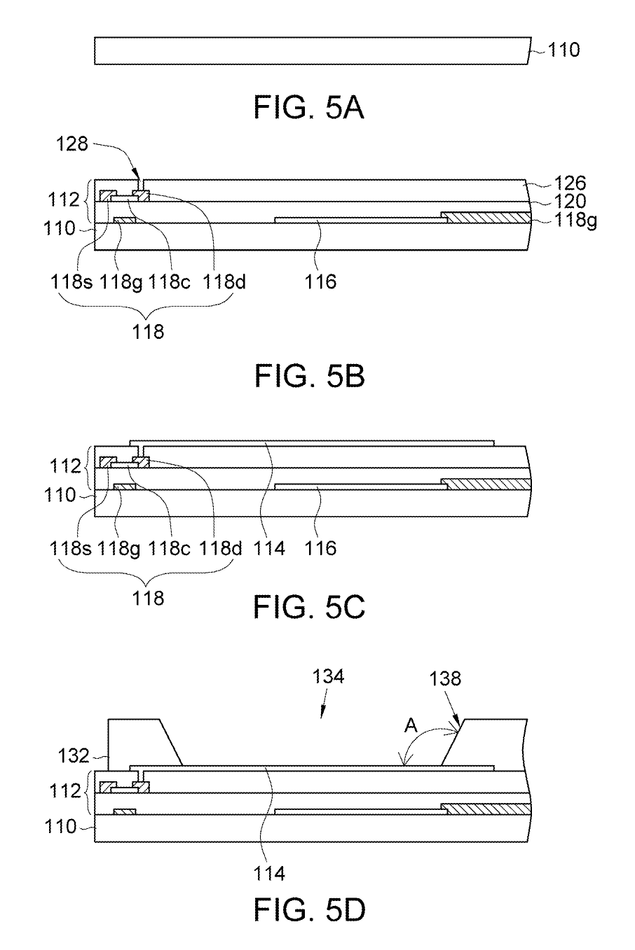

Firstly, referring to both FIG. 5A, a bottom substrate of FIG. 3 is shown. The method begins at step S402, a bottom substrate 110 is provided.

Next, referring to both FIG. 2 and FIG. 5B. FIG. 5B shows a bottom substrate of FIG. 5A with an active array structure layer. In step S404, an active array structure layer 112 is formed on the bottom substrate 110. The active array structure layer 112 includes a transparent bottom electrode 116, a plurality of transistor structures 118, an insulation layer 120, a passivation layer 126, a plurality of scan lines 122, a plurality of data lines 124 and a contact hole 128. The insulation layer 120 covers the transparent bottom electrode 116. In the present embodiment of the invention, the storage capacitor structure is exemplified by a type of Cs-on-Gate. As indicated in FIG. 5B, the transparent bottom electrode 116 is electrically connected to the gate 118g at the right-hand side of FIG. 5B. The formation of the transparent bottom electrode 116 and the gate 118g is exemplified low below. Firstly, a transparent bottom electrode layer (not illustrated) is formed, and then the transparent bottom electrode layer is patterned to form a transparent bottom electrode 116. Next, a metal layer (not illustrated) is further formed on the transparent bottom electrode 116, and then the metal layer is patterned to form the gate 118g of FIG. 5B.

Then, referring to both FIG. 5C, a bottom substrate of FIG. 5B with a transparent pixel electrode is shown. In step S406, a transparent pixel electrode 116 is formed on the active array structure layer 112, wherein each transparent pixel electrode 116 partially overlaps the corresponding transparent bottom electrode 116 to form a plurality of storage capacitor structures, and is electrically connected to the drain 118d of the transistor structure 118 through the contact hole 128 (illustrated in FIG. 5B).

Afar that, referring to both FIG. 5D, a bottom substrate of FIG. 5C with a cushion layer is shown. In step S408, a cushion layer 132 is formed on the active array structure layer 112, wherein the cushion layer 132 has a plurality of recesses 134 for respectively exposing the transparent pixel electrode 114, and an obtuse angle A is contained between the side-wall 138 of the recess 134 and the corresponding transparent pixel electrode 114 for enabling the liquid crystal molecules 108 (illustrated in FIG. 3) to be arranged in a multi-domain to increase the range of the viewangle of the transflective LCD panel 100 and reduce the response time of the liquid crystal molecules 108.

Lastly, the method proceeds to step S410, a reflective metal layer 136 is formed on the cushion layer 132 for reflecting the environment light. Thus, the lower substrate 106 of FIG. 3 is completed.

According to the transflective LCD panel and the manufacturing method for a lower substrate thereof disclosed in the above embodiment of the invention, the storage capacitor structure located at the transmissive region of the pixel structure is a transparent structure formed by a transparent bottom electrode and a transparent pixel electrode. Thus, the storage capacitor can be increased to satisfy the high resolution requirement of the product without decreasing the aperture ratio of the transmissive region of the pixel structure. Besides, on the cushion layer, an obtuse angle is contained between the side-wall of the recesses and the corresponding transparent pixel electrode for enabling the liquid crystal molecules to be arranged in a multi-domain to increase the range of angle of view in the transflective LCD panel and reduce the response time of the liquid crystal molecules.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A transflective liquid crystal display (LCD) panel, comprising:
an upper substrate;
a liquid crystal layer comprising a plurality of liquid crystal molecules; and
a lower substrate substantially parallel to the upper substrate, wherein the liquid crystal layer is disposed between the upper substrate and the lower substrate, and the lower substrate comprises:
a bottom substrate;
an active array structure layer comprising a plurality of transparent bottom electrodes, a plurality of transistor structures, at least an insulation layer, a plurality of scan lines and a plurality of data lines, which are all formed on the bottom substrate, the at least one insulation layer covers the transparent bottom electrodes, the data lines and the scan lines define a plurality of pixels;
a plurality of transparent pixel electrodes formed on the active array structure layer, wherein each of the transparent pixel electrodes partially overlaps the corresponding transparent bottom electrode to form a plurality of storage capacitor structures;
a cushion layer formed on the active array structure layer, wherein the cushion layer has a plurality of recesses for respectively exposing the transparent pixel electrodes and enabling the liquid crystal molecules to be arranged in a multi-domain; and
a reflective metal layer formed on the cushion layer for reflecting the light;
wherein, at least a portion of one of the transparent bottom electrodes and at least a portion of the corresponding transparent pixel electrode are disposed at the transmissive region of the corresponding pixel.

2. The transflective LCD panel according to claim 1, wherein each of the pixels comprises the corresponding transistor structure, the corresponding transparent bottom electrode, the corresponding at least one insulation layer, and the corresponding transparent pixel electrode.

3. The transflective LCD panel according to claim 1, wherein at least a portion of each of the transistor structures is covered by the cushion layer.

4. The transflective LCD panel according to claim 3, wherein an obtuse angle is contained between the side-wall of the recesses and the corresponding transparent pixel electrode.

5. A manufacturing method for a lower substrate of a transflective LCD panel, wherein the transflective LCD panel comprises an upper substrate and a liquid crystal layer, the liquid crystal layer comprises a plurality of liquid crystal molecules, the lower substrate is substantially parallel to the upper substrate, the liquid crystal layer is disposed between the upper substrate and the lower substrate, and the manufacturing method comprises:
providing a bottom substrate;
forming an active array structure layer on the bottom substrate, wherein the active array structure layer comprises a plurality of transparent bottom electrodes, a plurality of transistor structures, at least an insulation layer, a plurality of scan lines and a plurality of data lines, which are all formed on the bottom substrate, the at least one insulation layer covers the transparent bottom electrodes, the data lines and the scan lines define a plurality of pixels;
forming a plurality of transparent pixel electrodes on the active array structure layer, wherein each of the transparent pixel electrodes partially overlaps the corresponding transparent bottom electrode to form a plurality of storage capacitor structures;
forming a cushion layer on the active array structure layer, wherein the cushion layer has a plurality of recesses for respectively exposing the transparent pixel electrodes and enabling the liquid crystal molecules to be arranged in a multi-domain; and
forming a reflective metal layer on the cushion layer for reflecting the light.
wherein, at least a portion of one of the transparent bottom electrodes and at least a portion of the corresponding transparent pixel electrode are disposed at the transmissive region of the corresponding pixel.

6. The manufacturing method according to claim 5, wherein an obtuse angle is contained between the side-wall of the recesses and the corresponding transparent pixel electrode.

7. The manufacturing method according to claim 5, wherein each of the pixels comprises the corresponding transistor structure, the corresponding transparent bottom electrode, the corresponding at least one insulation layer and the corresponding transparent pixel electrode.

8. The manufacturing method according to claim 5, wherein at least a portion of each of the transistor structures is covered by the cushion layer.
